(19) United States
(12) Patent Application Publication
(10) Pub. No.: US 2010/0052041 A1
(43) Pub. Date: Mar. 4, 2010

(54) Nonvolatile Memory Devices Having Charge-Trap Layers Therein with Relatively High Election Affinity

(76) Inventors: Junkyu Yang, Seoul (KR); Young-Geun Park, Gyeonggi-do (KR); Chunhyung Chung, Gyeonggi-do (KR); EunSok Choi, Gyeonggi-do (KR); Seon-Ho Jo, Gyeongsangnam-do (KR); Hanmei Choi, Seoul (KR); Young-Sun Kim, Gyeonggi-do (KR)

Correspondence Address: MYERS BIGEL SIBLEY & SAJOVEC, PO BOX 37428, RALEIGH, NC, 27627, US

(21) Appl. No.: 12/550,958

(22) Filed: Aug. 31, 2009

(30) Foreign Application Priority Data
Sep. 3, 2008 (KR) 2008-0086961

(51) Int. Cl. H01L 29/792

(52) U.S. Cl. 257/324; 257/E29.309

(57) ABSTRACT

Provided is a nonvolatile memory device. The nonvolatile memory device may include a tunnel insulating layer on a semiconductor substrate; a charge trap layer disposed on the tunnel insulating layer and having an electron affinity greater than a silicon nitride layer; a barrier insulating layer on the charge trap layer; a blocking insulating layer on the barrier insulating layer; and a gate electrode on the blocking insulating layer. An electron affinity of the barrier insulating layer is smaller than an electron affinity of the blocking insulating layer.

### REFERENCE TO PRIORITY APPLICATION

This U.S. patent application claims priority to Korean Patent Application No. 10-2008-0086961, filed Sep. 3, 2008, the contents of which are hereby incorporated herein by reference.

### FIELD OF THE INVENTION

The present invention relates to nonvolatile memory devices and, more particularly, to nonvolatile memory devices including charge trap layers therein.

### BACKGROUND

Generally, semiconductor memory devices are classified into volatile memory devices and nonvolatile memory devices. The volatile memory devices lose their stored data when a power supply is interrupted while the nonvolatile memory devices retain their stored data when a power supply is interrupted. A flash memory device is a high integration nonvolatile memory device developed by extracting advantages of an erasable programmable read only memory (EPROM) capable of programming and erasing and an electrically erasable programmable read only memory (EEPROM) capable of electrically programming and erasing.

A flash memory device may include a structure that a floating gate storing data and a control gate controlling the floating gate are sequentially stacked. That structure hinders a scaling down of a memory device because of a vertical height of a floating gate. A flash memory device using a charge trap layer has been developed to effectively reduce a vertical height of a memory cell and to maintain a retention characteristic of retaining stored data for a long time.

### SUMMARY

Some exemplary embodiments provide a nonvolatile memory device. The nonvolatile memory device may include a tunnel insulating layer on a semiconductor substrate; a charge trap layer disposed on the tunnel insulating layer and having an electron affinity greater than a silicon nitride layer; a barrier insulating layer on the charge trap layer; a blocking insulating layer on the barrier insulating layer; and a gate electrode on the blocking insulating layer. An electron affinity of the barrier insulating layer is smaller than an electron affinity of the blocking insulating layer.

Some exemplary embodiments provide a nonvolatile memory device. The nonvolatile memory device may include a tunnel insulating layer on a semiconductor substrate; a charge trap layer disposed on the tunnel insulating layer and including a hafnium oxide layer; a barrier insulating layer disposed on the charge trap layer and including a silicon oxide layer; a blocking insulating layer disposed on the barrier insulating layer and including an aluminum oxide layer; and a gate electrode on the blocking insulating layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross sectional view of a nonvolatile memory device according to embodiments of the present invention.

FIG. 2 is an energy band diagram of a nonvolatile memory device according to embodiments of the present invention.

FIG. 3 is an energy band diagram illustrating a characteristic of an interface layer according to embodiments of the present invention.

FIG. 4 is a graph illustrating a retention characteristic of a nonvolatile memory device according to embodiments of the present invention.

FIG. 5 is a block diagram of an electronic system including a nonvolatile memory device according to embodiments of the present invention.

FIG. 6 is a card system of an electronic system including a nonvolatile memory device according to embodiments of the present invention.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

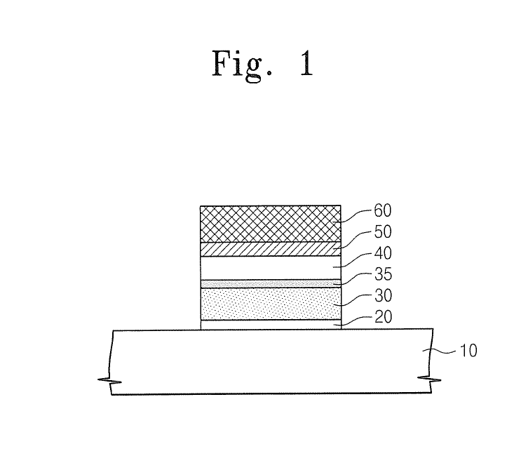

Referring to FIGS. 1 to 4, a nonvolatile memory device according to embodiments of the present invention is described. A tunnel insulating layer 20 is disposed on a semiconductor substrate 10. The tunnel insulating layer 20 may include at least any one of a silicon oxide layer and a silicon nitride layer. A silicon oxide layer constituting the tunnel insulating layer 20 is formed to have a thickness of more than 25 Å, thereby preventing a direct tunneling crossing a silicon oxide layer.

A charge trap layer 30 is disposed on the tunnel insulating layer 20. An electron affinity of the charge trap layer 30 may be greater than an electron affinity of a silicon nitride layer. Here, the electron affinity means an energy gap from an energy level of a vacuum state to an energy level of a lower edge of a conduction band. In addition, the charge trap layer 30 may have a dielectric constant greater than a dielectric constant of a silicon nitride layer. The charge trap layer 30 may be a hafnium oxide layer having an electron affinity greater than a silicon nitride layer. Also, the charge trap layer 30 may be at least any one of a zirconium oxide layer, a tantalum oxide layer, a hafnium silicon oxide layer, a hafnium oxynitride layer, a zirconium oxynitride layer, a hafnium silicon oxynitride, a hafnium aluminum oxynitride layer.

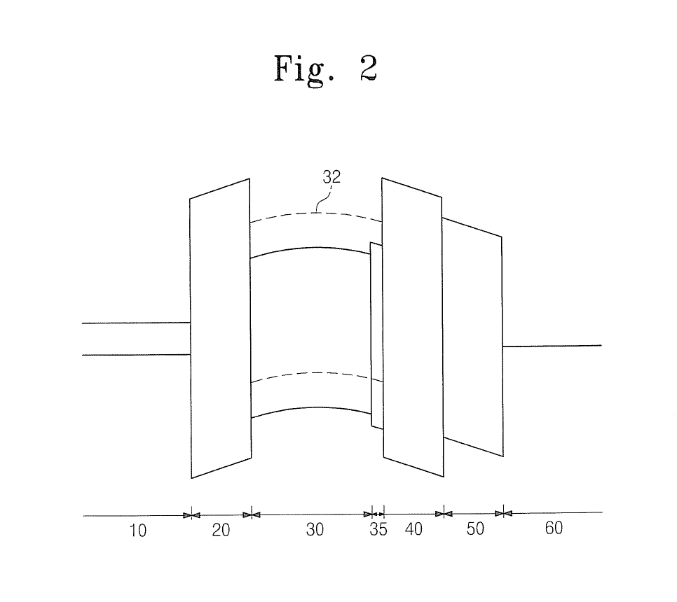

In FIG. 2, a silicon nitride layer 32 is represented as a dotted line and the charge trap layer 30 is represented as a solid line. For example, the charge trap layer 30 may be a hafnium oxide layer. The charge trap layer 30 may have a trap density higher than the silicon nitride layer 32. A nonvolatile memory device can increase a memory window and an efficiency of a program/erasure using a high trap density and a high dielectric constant by the charge trap layer 30. An increase of a memory window means an increase of the number of different states which a memory cell can have and also means an increase of a sensing margin. Charges can be effectively stored in the charge trap layer 30 due to a great electron affinity to improve a charge retention characteristic.

A barrier insulating layer 40, a blocking insulating layer 50 and a gate electrode 60 are sequentially disposed on the charge trap layer 30. An electron affinity of the barrier insulating layer 40 is smaller than an electron affinity of the blocking insulating layer 50 (referring to FIG. 2). Since the barrier insulating layer 40 has a small electron affinity, the number of charges ejected to the gate electrode 60 is reduced, thereby improving a retention characteristic.

The barrier insulating layer 40 may be a silicon oxide layer. The blocking 50 may include a high dielectric layer having a dielectric constant greater than the tunnel insulating layer 20. The blocking insulating layer 50 may include an insulating metal oxide layer. For example, the blocking insulating layer 50 may be an aluminum oxide layer. Also, the blocking insulating layer 50 may be a lanthanum hafnium oxide layer, a lanthanum aluminum oxide layer or a dysprosium scandium oxide layer.

The gate electrode 60 includes material having a work function of at least 4 eV. A tunneling probability of a charge moving to the charge trap layer 30 from the gate electrode 60 through the blocking insulating layer 50 is in inverse proportion to a work function of the gate electrode 60. The gate electrode 60 may be formed of a conductive layer having a work function of 4 eV or more. Thus, a tunneling probability of a charge moving through the blocking insulating layer can be lowered. The gate electrode 60 is an electric conductor having a work function of greater than 4 eV and may be formed of metal or silicon doped with a P-type impurity. For example, the gate electrode 60 may be P-type silicon, Ti, TiN, TaN, TaTi, TaSiN, Ta, W, Hf, HfN, Nb, Mo, RuO₂, RuO, Mo₂N, WN, WSi, NiSi, Ti₃Al, Ti₂AlN, Pd, Ir, Pt, Co, Cr, CoSi, NiSi or AlSi.

Referring to FIG. 2, a retention characteristic of a nonvolatile memory device is described. As shown in an energy band diagram of FIG. 2, since an electron affinity of the barrier insulating layer 40 is smaller than an electron affinity of the blocking insulating layer 50, the number of charges stored in the charge trap layer 30 ejected to the gate electrode 60 may be reduced. When the barrier insulating layer 40 is a silicon oxide layer, since the number of trap sites of the silicon oxide layer is less than that of a high dielectric layer, the number of charges ejected to the gate electrode 60 after being trapped in the barrier insulating layer 40 may be reduced.

A nonvolatile memory device may include an interface layer 35 disposed between the charge trap layer 30 and the barrier insulating layer 40. The interface layer 35 includes ingredients of the charge trap layer 30 and the barrier insulating layer 40 because the charge trap layer 30 and the barrier insulating layer 40 react to each other at the interface layer 35. When the charge trap layer 30 is a hafnium oxide layer and the barrier layer 40 is a silicon oxide layer, the interface layer 35 is a hafnium silicon oxide layer. A trap depth of the interface layer 35 is greater than a trap depth of the hafnium aluminum oxide layer. Here, the trap depth means a difference of an energy state between a lower edge of a conduction band and a trap energy level.

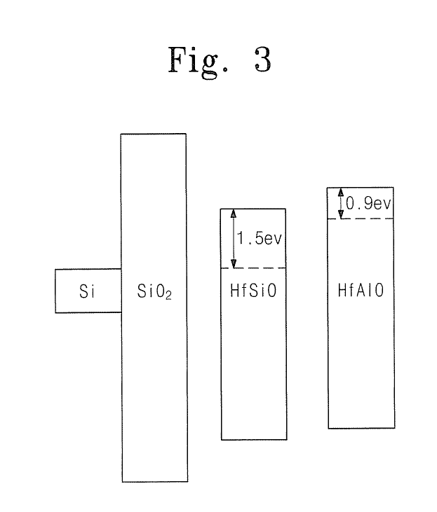

Referring to FIG. 3, when the interface layer 35 is a hafnium silicon oxide layer, a trap depth is 1.5 eV. When the barrier insulating layer 40 is not exist, a trap depth of a hafnium aluminum oxide layer formed by a reaction of the blocking insulating layer 50 and the charge trap layer 30 is 0.9 eV. Thus, a charge retention characteristic may be improved by the interface layer 35 formed by a reaction of the barrier insulating layer 40 and the charge trap layer 30.

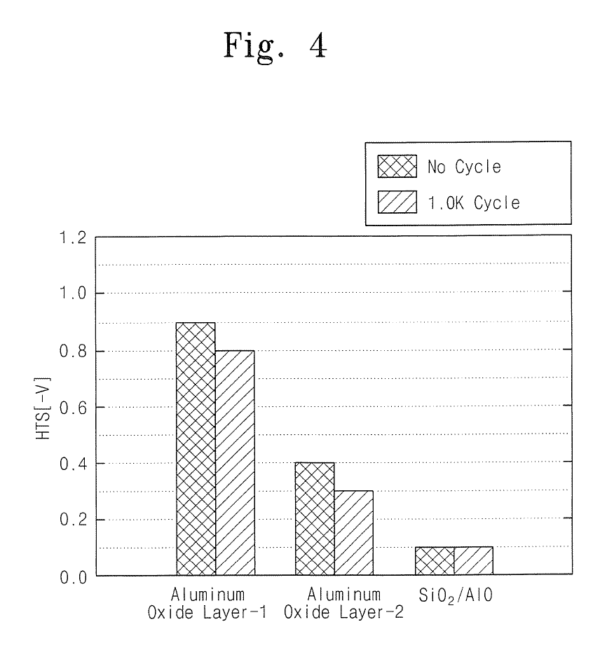

Referring to FIG. 4, an aluminum oxide layer-1 and an aluminum oxide layer-2 represent the case that a barrier insulating layer is not existed and a blocking insulating layer is an aluminum oxide layer. A thickness of the aluminum oxide layer-1 is smaller than a thickness of the aluminum oxide layer-2. A SiO₂/AlO represents the case that a barrier insulating layer is existed according to embodiments of the present invention. Here, the barrier insulating layer is a silicon oxide layer and the blocking insulating layer is an aluminum oxide layer. In FIG. 4, a high temperature storage (HTS) is a parameter representing what degree the data state is maintained when leaving a nonvolatile memory device at a high temperature for a specific time after programming the nonvolatile memory device. For example, after programming a nonvolatile memory device and leaving the nonvolatile memory device at a temperature of 200° C. for two hours, a threshold voltage of the nonvolatile memory device can be measured. A HTS in the case that a barrier insulating layer exists is superior compared with the case that a barrier insulating layer does not exist. A HTS measured after repeatedly performing a program/erasure operation 100 times is similar to a HTS measured without repeatedly performing a program/erasure operation. Since the aluminum oxide layer-2 is thicker than the aluminum oxide layer-1, a retention characteristic of the aluminum oxide layer-2 is superior. That is, since a moving distance of a charge is lengthened due to a thickness of the aluminum oxide layer, a loss of a charge is reduced.

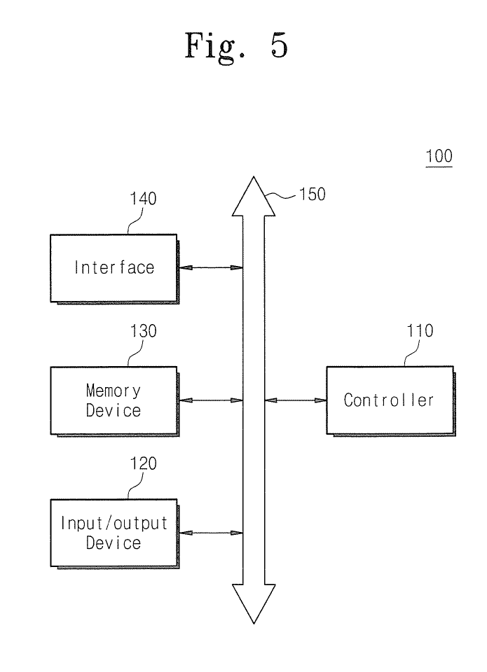

FIG. 5 is a block diagram of an electronic system including a nonvolatile memory device according to embodiments of the present invention.

Referring to FIG. 5, an electronic system 100 may include a controller 110, an input/output device 120 and a memory device 130. The controller 110, the input/output device 120 and the memory device 130 may be coupled to one another through a bus 350. The bus 150 may be a path through which data transfer. The controller 110 may include at least one of a micro processor, a digital signal processor, a microcontroller and a logic device having a function similar to the micro processor, the digital signal processor, the microcontroller. The input/output device 120 may include at least one selected from a keypad, a keyboard and a display device. The memory device 130 is a device storing data. The memory device 130 may store data and/or an instruction executed by the controller 110. The memory device 130 may include a nonvolatile memory device disclosed in embodiments described above. The electronic system 100 may further include an interface 140 for transmitting data to a communication network or receiving data from a communication network. The interface 140 may be a wireline/wireless shape. The interface 140 may include an antenna or a wireline/wireless transceiver.

The electronic system 100 may be embodied by a mobile system, a personnel computer, an industrial computer or a logic system performing a variety of functions. For example, the mobile system may be one of a personal digital assistant (PDA), a portable computer, a web tablet, a mobile phone, a wireless phone, a laptop computer, a memory card, a digital music system and a data transmission/receipt system. When the electronic system 300 is a device which can perform a wireless communication, the electronic system 300 may be used in a communication interface protocol of a third generation such as CDMA, GSM, NADC, E-TDMA, CDMA2000.

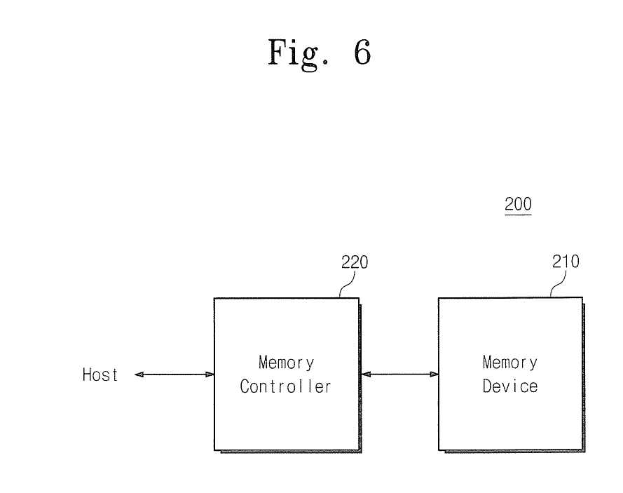

FIG. 6 is a card system of an electronic system including a nonvolatile memory device according to embodiments of the present invention.

Referring to FIG. 6, a memory card 200 may include a memory device 210 and a memory controller 220. The memory device 210 can store data. The memory device 210 may have a nonvolatile characteristic retaining stored data even when a power supply is interrupted. The nonvolatile memory device 210 may include a nonvolatile memory device disclosed in embodiments described above. The memory controller 220 can readout data stored in the memory device 210 or store data in the memory device 210 in response to a request of decoding/writing of a host.

What is claimed is:

1. A charge-trap type nonvolatile memory device, comprising:
a tunnel insulating layer on a semiconductor region;
a charge-trap layer on the tunnel insulating layer, said charge-trap layer comprising a material having a greater electron affinity relative to silicon nitride;
a barrier insulating layer on said charge-trap layer;
a blocking insulating layer on said barrier insulating layer, said blocking insulating layer comprising a material having a greater electron affinity relative to said barrier insulating layer; and
a gate electrode on said blocking insulating layer.

2. The device of claim 1, wherein said barrier insulating layer comprises silicon dioxide.

3. The device of claim 1, wherein said blocking insulating layer comprises aluminum oxide.

4. The device of claim 1, wherein said blocking insulating layer comprises a material selected from a group consisting of lanthanum hafnium oxide, lanthanum aluminum oxide and dysprosium scandium oxide.

5. The device of claim 1, wherein said charge trap layer is a hafnium oxide layer.

6. The device of claim 1, wherein said charge trap layer comprises a material selected from a group consisting of zirconium oxide, tantalum oxide, hafnium silicon oxide, hafnium oxynitride, zirconium oxynitride, hafnium silicon oxynitride and hafnium aluminum oxynitride.

7. The device of claim 1, wherein said tunnel insulating layer comprises a material selected from a group consisting of silicon oxide and silicon oxynitride.

8. The device of claim 1, wherein said gate electrode comprises a material having a work function of at least 4 eV.

9. A nonvolatile memory device comprising:
a tunnel insulating layer on a semiconductor substrate;
a charge trap layer on the tunnel insulating layer and including a hafnium oxide layer;
a barrier insulating layer on the charge trap layer and including a silicon oxide layer;
a blocking insulating layer on the barrier insulating layer and including an aluminum oxide layer; and
a gate electrode on the blocking insulating layer.

10. The nonvolatile memory device of claim 9, further comprising an interface layer disposed between the charge trap layer and the barrier insulating layer.

11. The nonvolatile memory device of claim 10, wherein a trap depth of the interface layer is greater than a trap depth of the hafnium oxide layer.

12. The nonvolatile memory device of claim 11, wherein the interface layer is a hafnium silicon oxide layer formed by a reaction of the charge trap layer and the barrier insulating layer at an interface layer.

13. A nonvolatile memory device comprising:
a tunnel insulating layer on a semiconductor substrate;
a charge trap layer on the tunnel insulating layer and having an electron affinity greater than a silicon nitride layer;
a barrier insulating layer on the charge trap layer;
a blocking insulating layer on the barrier insulating layer; and
a gate electrode on the blocking insulating layer,
wherein an electron affinity of the barrier insulating layer is smaller than an electron affinity of the blocking insulating layer.

14. The nonvolatile memory device of claim 13, further comprising an interface layer disposed between the charge trap layer and the barrier insulating layer.

15. The nonvolatile memory device of claim 14, wherein the interface layer is formed by a reaction of the charge trap layer and the barrier insulating layer at an interface and comprises ingredients of the charge trap layer and the barrier insulating layer.

16. The nonvolatile memory device of claim 13, wherein the barrier insulating layer is a silicon oxide layer.

17. The nonvolatile memory device of claim 13, wherein the blocking insulating layer is an aluminum oxide layer.

18. The nonvolatile memory device of claim 13, wherein the blocking insulating layer is any one of lanthanum hafnium oxide layer, a lanthanum aluminum oxide layer or a dysprosium scandium oxide layer.

19. The nonvolatile memory device of claim 13, wherein the charge trap layer is a hafnium oxide layer.

20. The nonvolatile memory device of claim 13, wherein the charge trap layer is any one of a zirconium oxide layer, a tantalum oxide layer, a hafnium silicon oxide layer, a hafnium oxynitride layer, a zirconium oxynitride layer, a hafnium silicon oxynitride, a hafnium aluminum oxynitride layer.

21. The nonvolatile memory device of claim 13, wherein the tunnel insulating layer is any one of a silicon oxide layer and a silicon oxynitride layer.

22. The nonvolatile memory device of claim 13, wherein the gate electrode comprises material having a work function of at least 4 eV.
